(19) United States
(12) Patent Application Publication
(10) Pub. No.: US 2012/0097641 A1
(43) Pub. Date: Apr. 26, 2012

(54) METHOD AND DEVICE FOR PLASMA TREATMENT OF A FLAT SUBSTRATE

(75) Inventors: Rudolf Beckmann, Hammersbach (DE); Michael Geisler, Wachtersbach (DE); Arndt Zeuner, Alzenau (DE); Marks Fiedler, Frankfurt am Main (DE); Gunter Grabosch, Frankfurt am Main (DE); Andreas Pflug, Braunschweig (DE); Uwe Czarnetzki, Essen (DE); Ralf-Peter Brinkmann, Erkrath (DE); Michael Siemers, Braunschweig (DE)

(73) Assignees: FRAUNHOFER GESELLSCHAFT ZUR FORDERUNG DER ANGWANDTEN FORSCHUNG E.V., Munchen (DE); RUHR-UNIVERSITAT BOCHUM, Bochum (DE); LEYBOLD OPTICS GMBH, Alzenau (DE)

(21) Appl. No.: 13/127,497

(22) PCT Filed: Nov. 4, 2009
(86) PCT No.: PCT/EP2009/007905

§ 371 Date: Oct. 24, 2011

(30) Foreign Application Priority Data
Nov. 4, 2008 (DE) 10 2008 055 786
May 8, 2009 (DE) 10 2009 020 436

(51) Int. Cl. B44C 1/22; C23C 16/50

(52) U.S. Cl. 216/67; 427/569; 118/723 E; 156/345.43

(57) ABSTRACT

Method and device for the plasma treatment of a substrate in a plasma device, wherein—the substrate (110) is arranged between an electrode (112) and a counter-electrode (108) having a distance d between a surface area of the substrate to be treated and the electrode, —a capacitively coupled plasma discharge is excited, forming a DC self-bias between the electrode (112) and the counter-electrode (108), —in an area of the plasma discharge between the surface area to be treated and the electrode having a quasineutral plasma bulk (114), a quantity of at least one activatable gas species, to which a surface area of the substrate to be treated is subjected, is present —it is provided that a plasma discharge is excited, —wherein the distance d has a value comparable to s=se+sg, where se denotes a thickness of a plasma boundary layer (119) in front of the electrode, and sg denotes a thickness of a plasma boundary layer (118) in front of the substrate surface to be treated or —wherein the quasineutral plasma bulk (114) between the surface area to be treated and the electrode has a linear extension dp, where dp<⅓d, dp<max(se+sg) or dp<0.5s.

### TECHNICAL FIELD

The invention relates to a method and a device for the plasma treatment of a substrate respectively.

### BACKGROUND

Devices for the plasma treatment of flat substrates are known. For example, EP 312 447 B1 describes a device for the plasma deposition (PECVD) of thin layers on sheet-like substrates for electronic or optoelectronic applications.

In the unpublished DE 10 2007 022 252.3 a description is given of a system for the plasma coating of large-area flat substrates, it being possible for the substrate area to be of the order of magnitude of 1 m² and more. The plasma is produced between an electrode and a counter-electrode, between which the substrate to be treated is introduced. The system comprises a device for varying the relative distance between the electrodes, a first, relatively large distance being provided when the substrate is being loaded into or unloaded from the process chamber and a second, relatively small distance being provided when the treatment of the substrate is being carried out. A layer-forming reaction gas or reaction gas mixture is supplied via a gas spray integrated in the electrode. The gas spray comprises a gas spray outlet plate with a multiplicity of outlet openings, with the aid of which the reaction gas is introduced into the process chamber in a uniformly distributed manner. The reaction gas lies in a quasineutral plasma bulk of the plasma discharge, having a relatively high electron density, between the substrate to be treated and the gas spray as an activated gas species, to which the substrate to be treated is exposed. The speed and quality of the substrate coating depends on many process parameters, in particular on the pressure, flux and composition of the reaction gases, on the power density and on the frequency of the plasma excitation as well as the substrate temperature.

If the process parameters are changed for the simultaneous achievement of high coating rates and high layer quality, problems occur, in particular in the case of large-area substrates, and some of these problems are briefly discussed below.

Firstly, apart from the desired coating of the substrate, there is also an undesired coating of further components of the system, in particular a coating of parts of the gas spray by them being exposed to an activated gas species from the quasineutral plasma bulk, which leads to a loss of expensive reaction gas and to increased expenditure of purifying gases.

To increase the coating rate, it is generally required to increase the power density of the plasma, which however can lead to a higher ion bombardment of the substrate, and consequently can adversely influence the quality of the layer deposited.

In the case of plasma excitation with a 13.56 MHz radio-frequency voltage, even a large electrode area can be supplied with high voltage very homogeneously in a simple way, but with increasing power density an undesired ion bombardment of the substrate increases. In the case of plasma excitation with a VHF radio-frequency voltage (27 MHz—about 150 MHz), though the ion bombardment of the substrate is low even with high power densities, as described for example in the article by Amanatides, Mataras and Rapakoulias, Journal of Applied Physics Volume 90, Number 11, December 2001, a homogeneous distribution of the VHF radio-frequency voltage over a large area can only be achieved with great effort.

EP 0688469 B1 already discloses a plasma-assisted machining or manufacturing method in which gas discharges are excited with an anharmonic alternating voltage, the frequency spectrum of which is made up of a fundamental frequency and an integral multiple of this fundamental frequency. In this case, the amplitudes of the individual frequency components are adapted to the requirements of the plasma-assisted method. The term anharmonic should be understood here in the sense of non-harmonic, that is to say sinusoidal. Among the aims of this known method is the creation of a process-specific ion distribution to improve plasma-assisted machining and manufacturing methods for thin layers, without however specifying how the relative ion bombardment of the electrodes could be influenced.

In the case of plasma reactors with a parallel plate arrangement, with a constant power density of the plasma excitation, the relative ion bombardment of the electrodes is determined by the area ratio of the electrode and the counter-electrode and reflects the relative ratio of the average voltage dropping across the plasma boundary layer in front of the electrode or the counter-electrode. As shown in the article by Heil, Czarnetzki, Brinkmann and Mussenbrock, J. Phys D: Appl. Phys. 41 (2008) 165002, the absolute value of the voltages mentioned scales with a power close to 2 with the area ratio of the area of the electrode to the area of the counter-electrode. Since the areas of the electrode and the counter-electrode have to be almost the same size in the manufacture of substrates to be homogeneously coated, the possibilities of using a geometrical asymmetry to influence the energy of the ion energy to which the electrode and the counter-electrode are exposed are limited.

An alternative method, independent of geometrical asymmetry, of influencing the energy of the ions to which the electrode and counter-electrode are exposed with a given excitation frequency and voltage was described in the aforementioned article by Heil, Czarnetzki, Brinkmann and Mussenbrock. According to this, a DC self-bias is established by means of an RF voltage which has at least two harmonic frequency components with a prescribed relative phase relationship to each other, at least one of the higher frequency components being an even-numbered harmonic of a lower frequency component. In dependence on the relative phase relationship between the two harmonic frequency components, a setting of a relative ratio of ion energies at the electrode and the counter-electrode can be performed.

### BRIEF SUMMARY

The invention makes possible a plasma treatment of a substrate in which a relative change in the exposure of the electrode and the substrate to an activated gas species can be achieved, the substrate being arranged between an electrode and a counter-electrode and the activated gas species being present in a quasineutral plasma bulk between the electrode and the counter-electrode.

In respect of the method according to the invention for the plasma treatment of a substrate in a plasma device, it is initially provided that
the substrate is arranged between an electrode and a counter-electrode with a distance d between a surface region to be treated of the substrate and the electrode,
a capacitively coupled plasma discharge with formation of a DC self-bias is excited between the electrode and the counter-electrode,
in a region of the plasma discharge between the surface region to be treated and the electrode with a quasineutral plasma bulk there is a quantity of at least one activatable gas species to which a surface region to be treated of the substrate is exposed.

The method is distinguished by the excitation of a plasma discharge
in which the distance d has a value in a range between s and 2.5s, with s=se+sg, where se denotes a thickness of a plasma boundary layer in front of the electrode and sg denotes a thickness of a plasma boundary layer in front of the counter-electrode or
in which the quasineutral plasma bulk between the surface region to be treated and the electrode has a linear extent dp, with dp<⅓d, dp<max(se+sg) or dp<0.5s.

The invention makes it possible, by the specified values of d, se, sg and dp, which characterize a specific geometry of the plasma discharge, to set in dependence on a value of the DC self-bias a rate with which a surface region to be treated of the substrate is exposed to the activated gas species.

The DC self-bias is in this case dependent on the ratio of the areas of the two electrodes. The plasma discharge is excited by means of a radio-frequency voltage, provided by an RF generator, in a process gas fed into the region between the electrodes, for example argon and/or hydrogen, with an excitation frequency in the range of 1 to 40 MHz, preferably 13.56 MHz. The substrate is directly in front of the counter-electrode, it being self-evident that the terms “electrode” and “counter-electrode” are purely conventional and interchangeable. It is presupposed in respect of the method that the voltage applied for the excitation of the plasma drops predominantly in the region of the plasma boundary layer in front of the electrode and the counter-electrode and only a little in the region of the quasineutral plasma bulk. With a substrate arranged in front of the counter-electrode, the plasma boundary layer extends from the substrate surface to the quasineutral plasma bulk.

In the case of a plasma discharge with a DC self-bias, the thickness of the plasma boundary layer in front of the electrode or the counter-electrode differs, a lower average voltage dropping across the boundary layer with the smaller thickness. If the value d is comparable to s=se+sg, that is to say d assumes a value approximately equal to s, where se is a thickness of a plasma boundary layer in front of the electrode and sg is a thickness of a plasma boundary layer in front of the counter-electrode, the extent of the quasineutral plasma bulk is inevitably relatively small. The plasma boundary layer in front of the counter-electrode in this case extends up to the surface of the substrate surface to be treated. A value d in a range between 1.1s and 2.5s is preferred, a value d in a range between 1.1s and 1.2s, 1.4s, 1.6s, 1.8s or 2.0s is particularly preferred.

The rate with which the electrode or the substrate is exposed to the activated gas species present in the neutral plasma bulk is dependent in the method according to the invention on the position of the region of the highest concentration of the activated gas species, and consequently in the case of a relatively narrow quasineutral plasma bulk mainly on the distance between the quasineutral plasma bulk and the electrode or the substrate, and increases respectively with decreasing distance between the quasineutral plasma bulk and the electrode or the substrate. This distance is determined by the thickness of the plasma boundary layer se or sg, which in the case of a DC self-bias assumes different values. The quasineutral bulk lies closer to the electrode or the counter-electrode in front of which the boundary layer with the smaller thickness lies. Therefore, the way in which the electrode or substrate is relatively exposed to the activated gas species with the distance d according to the invention can be influenced by changing the thickness of the plasma boundary layer se and sg.

According to a further aspect of the invention, the quasineutral plasma bulk has a linear extent dp<⅔d, dp<max (se, sg) or dp<0.5s. The linear extent dp of the quasineutral plasma bulk is taken to be the thickness of the quasineutral plasma bulk parallel to a cross-sectional diameter between the opposing areas of the electrode and the substrate. Also in these cases, the rate with which the substrate is exposed to activated gas species from the quasineutral plasma bulk can be controlled in dependence on the value of the DC self-bias.

The values of the parameters d, se, sg and dp can be varied or set in dependence on parameters of the plasma discharge, such as discharge voltage, excitation frequency or power density, so that d assumes a value in a range between 1.1s and 2.5s, with particular preference a value d in a range between 1.1s and 1.2s, 1.4s, 1.6s, 1.8s or 2.0s, or that dp<⅔d, dp<max (se, sg) or dp<0.5s.

A variation of d with constant values of se, sg and dp and a variation of se, sg and dp with a constant value of d is preferred.

The respective values of the thickness of the plasma boundary layer in front of the electrode and the counter-electrode or the substrate surface and the thickness of the quasineutral plasma bulk may be determined in a way known per se. Said values may preferably be determined by methods of optical plasma diagnostics, for example by means of laser diagnostics. It is self-evident that said values can also be determined theoretically and/or by computer simulation.

In a refinement of the invention, it is provided that the relative position of a geometrical center of gravity of the quasineutral plasma bulk between the electrode and the counter-electrode is set or changed in dependence on a value of the distance d or of the DC self-bias, whereby the exposure of the substrate and the electrode to the activated gas species can be influenced to optimize the plasma treatment.

In a further refinement of the invention, the position of the geometrical center of gravity is shifted in the direction of the surface to be treated in relation to the position of said center of gravity in the case of a plasma discharge without DC self-bias, and consequently the exposure of the surface to be treated to activated gas species is advantageously increased.

In a further embodiment of the invention, the plasma treatment comprises a plasma coating, in particular as used in the manufacture of solar cells and flat screens.

Furthermore, the plasma treatment may comprise a surface modification by the plasma, using the effect of an ion bombardment and of the activated gas species on the surface structure and the composition of the substrate. Furthermore, the plasma treatment may also comprise an etching of the substrate, using the influence of the ion bombardment and of the activated gas species on the etching of a surface.

Generally, the excitation of the precursor gas may take place thermally (CVD), by plasma excitation (PECVD) or by optical excitation (photo CVD).

In a refinement of the invention, an activation of the gas species takes place by radical formation in the quasineutral plasma bulk itself, since the increased electron density in the plasma bulk makes radical formation easier. The quasineutral plasma bulk is in this case a source region and region of highest concentration of activated gas species.

In a further embodiment of the invention, a precursor gas which can form layer-creating radicals in a plasma is used as the gas species. The precursor gas is preferably silane (SiH₄), which forms the layer precursor SiH₃ in the plasma by electron collision. The precursor gas may also be CH₄, TEOS (Si(OC₂H₅)₄) or other gases which can be admitted into the process chamber in a gaseous state. These compounds are stable, and require excitation to be converted into a species capable of layer formation.

In a further embodiment, it is provided that a purifying gas which can form reactive radicals in a plasma, such as for example NF₃, is used as the activatable gas species.

The spatial region in which an activation of the activatable gas species takes place in the plasma bulk is of significance for an optimum design of the plasma device with regard to the avoidance of parasitic coating, in particular when coating with silane or similar layer-forming gases. As explained in the publication by A. Pflug, M. Siemers, B. Szyszka, M. Geisler and R. Beckmann “Gas Flow and Plasma Simulation for Parallel Plate PACVD Reactors, 51st SVC Technical Conference, Apr. 23, 2008 Chicago, in the case of a plasma discharge of a silane/hydrogen plasma in a parallel plate reactor, the formation of the activated gas species takes place by plasma-activated dissociation of silane in the region of the quasineutral plasma bulk. Therefore, the coating of the substrate surface to be treated can be advantageously increased in relation to the coating of the electrode by the choice according to the invention of the values of d, se, sg and dp, which characterize the geometry of the plasma discharge.

In a further embodiment of the invention, a process gas and/or an activatable gas species is transported into the region between the electrode and the counter-electrode by means of an electrode which comprises a gas distribution device with a multiplicity of outlet openings for gas, since a greater homogeneity of the exposure of a substrate surface to be treated can be achieved in this way.

According to a further embodiment, preferred for flat substrates, the DC self-bias can be achieved very easily by a geometrical asymmetry of the electrode and the counter-electrode.

In a preferred embodiment of the invention, an RF voltage which has at least two harmonic frequency components with a prescribed relative phase relationship to each other (mixed frequency), at least one of the higher frequency components being an even-numbered harmonic of a lower frequency component, is used for establishing the DC self-bias. The forming of the DC self-bias achieved in this way is referred to hereafter as the electrical asymmetry effect.

The electrical asymmetry effect allows an asymmetric distribution of the electron density to be established in the quasineutral plasma bulk. With an otherwise homogeneously distributed electron temperature or energy distribution function in the quasineutral plasma bulk, the source intensity for producing radicals in the quasineutral plasma bulk can then be assumed to be proportional to the electron density. The exposure of the electrodes to activated gas species, i.e. the flux of radicals to the electrodes, is then given by the density profile of the electrons obtained by the diffusion equation. This is shown below for the case of completely adsorbing electrodes. The case of not completely adsorbing electrodes can be treated analogously with changed boundary conditions.

The electrodes are assumed to be localized on a normalized linear scale with x=□1. N denotes the density of the radicals and f(x) denotes a source function proportional to the electron density. It thus follows that:

$$- \frac{{\partial }^{2} N}{\partial {x}^{2}} = f ( x ) with N ( \pm 1 ) = 0 \qquad ( 1 )$$

On the basis of Fick's law, the flux is proportional to the derivative of the density with respect to the location. R is assumed to denote the ratio of the absolute values of the fluxes to the two electrodes:

$$R = \vert \frac{\frac{\partial N}{\partial x} {\vert}_{+ 1}}{\frac{\partial N}{\partial x} {\vert}_{- 1}} \vert \qquad ( 2 )$$

By elementary integration of equation (1), the following is obtained as a solution:

$$\frac{\partial N}{\partial x} {\vert}_{+ 1} = - \frac{1}{2} {\int }_{- 1}^{1} ( x + 1 ) f ( x ) d x \\ and \\ \frac{\partial N}{\partial x} {\vert}_{- 1} = - \frac{1}{2} {\int }_{- 1}^{1} ( x - 1 ) f ( x ) d x \qquad ( 3 )$$

As an example, the extreme case of a delta-shaped source function at the location x=s will be discussed here: f(x)=a□(x−s). This then gives:

$$R = \frac{1 + s}{1 - s} \qquad ( 4 )$$

It can be clearly seen how, by variation of the location s between −1 and 1, any ratios between zero and infinity can be set.

Alternatively, the contrast function K may also be used as the characteristic variable. This is given by the quotient of the difference of the absolute values of the fluxes and the sum of the absolute values of the fluxes. In the present case, the flux to the electrode is positive with x=+1 and negative with x=−1. Allowing for this change of sign, the following is obtained:

$$K = \frac{{\int }_{- 1}^{1} xf ( x ) d x}{{\int }_{- 1}^{1} f ( x ) d x} \qquad ( 5 )$$

For the delta function example considered above, K=s is consequently obtained. K therefore varies between −1 and +1, negative values indicating a dominance of the flux to the electrode with x=−1 and positive values indicating a dominance to the electrode with x=+1.

The electrical asymmetry effect makes it possible for the ion energy and the ion flux to which the electrode and the substrate are exposed to be controlled independently of each other.

It is preferred to use such a way of establishing the DC self-bias when there is geometrical symmetry of the electrode and the counter-electrode, in particular with a plasma device which is designed for the treatment of flat substrates with a surface to be treated of more than >1 m², for example 1.2 m×1.2 m.

Preferred methods and devices for establishing a DC self-bias are described in the unpublished patent application PCT/EP 2008/059133, the full disclosure content of which is made the disclosure content of the present patent application by reference.

According to a further embodiment of the invention, the DC self-bias is changed in dependence on the relative phase relationship between the harmonic frequency components and/or the amplitudes of the two harmonic frequency components of the RF voltage, whereby the ion energy and ion flux to which the substrate is exposed can be dynamically controlled during a plasma treatment.

It is particularly preferred if, in dependence on the relative phase relationship between two harmonic frequency components, a setting of a relative ratio of the ion energy at the electrode and the counter-electrode or the substrate is performed, whereby changing the ion energy is possible without major changes in the ion fluxes.

It is preferred if the substrate, the electrode and the counter-electrode have a flat surface. Said surfaces are preferably planar. It is self-evident that the substrate, the electrode and the counter-electrode may also have concave or convex surfaces.

A plasma coating of substrates with an area of 1 m² and more by means of a precursor gas is preferred in particular.

In the production of amorphous or microcrystalline coatings, a process gas pressure between 100 Pa and 2000 Pa, in particular 1300 Pa, and a power density between 0.01 W/cm³ and 5 W/cm³, in particular 1 W/cm³, is preferred. The output power of the RF generator lies in a range between 50 W and 50 kW, preferably at 1 kW.

In particular in the production of amorphous or microcrystalline coatings, values of se between 2 mm and 10 mm and values of sg between 1 mm and 5 mm are preferred. Furthermore, values of dp between 1 mm and 5 mm are preferred. A preferred value of d lies between 5 mm and 20 mm.

The device according to the invention for the plasma treatment of a substrate comprises
means for exciting a capacitively coupled plasma discharge, having a DC self-bias, in a region between an electrode and a counter-electrode and
means for transporting a quantity of at least one activatable gas species into a region of the plasma discharge with a quasineutral plasma bulk, wherein
the substrate is arranged or can be arranged between the electrode and the counter-electrode with a distance d between a surface region to be treated of the substrate and the electrode.

The device is designed in such a way that a plasma discharge with a DC self-bias can be excited.

The device is distinguished by the provision of a control unit for activating the device, so as to obtain a plasma discharge
in which the distance d has a value in a range between s and 2.5s, where se denotes a thickness of a plasma boundary layer in front of the electrode and sg denotes a thickness of a plasma boundary layer in front of the counter-electrode or
in which the quasineutral plasma bulk between the surface region to be treated and the electrode has a linear extent dp, with dp<⅓d, dp<max(se+sg) or dp<0.5s.

The advantages of the device correspond to those of the method according to the invention.

The control unit comprises means for producing the plasma discharge having the DC self-bias by means of an RF voltage, the RF voltage having at least two harmonic frequency components with a prescribed relative phase relationship to each other and at least one of the higher frequency components being an even-numbered harmonic of a lower frequency component.

To determine the respectively present values of the thickness of the plasma boundary layer in front of the electrode and the counter-electrode or the substrate surface and the thickness of the quasineutral plasma bulk, means for plasma diagnostics that are known per se are provided, supplying input values for the control unit. Means for optical plasma diagnostics, for example for plasma laser diagnostics, are preferably provided.

### BRIEF DESCRIPTION OF THE DRAWINGS

The invention is described in more detail below on the basis of exemplary embodiments and drawings disclosing further aspects and advantages of the invention, even independently of the summary given in the patent claims.

In the schematic drawing:

FIG. 1 shows a device according to the invention for the plasma treatment of flat substrates

FIG. 2 shows a device according to the invention for the plasma treatment of flat substrates

FIG. 3 shows a profile of the electrical potential and of the concentration of a layer-forming activated gas species in a region between an electrode and a counter-electrode for a harmonic RF excitation voltage and an excitation voltage with a mixed frequency.

### DETAILED DESCRIPTION

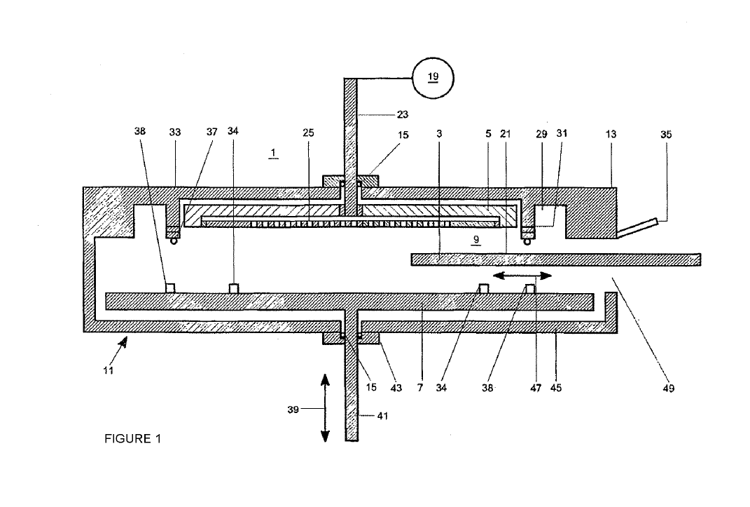

FIG. 1 shows in a simplified representation a plasma device (reactor 1) for the treatment of preferably flat and rectangular substrates 3. The reactor 1 may be designed, for example, as a PECVD reactor. The reactor 1 comprises means for exciting a capacitively coupled plasma discharge, having a DC self-bias, in a region between an electrode and a counter-electrode, in particular a process chamber 9 with an electrode 5 and a grounded counter-electrode 7, which are designed for producing a plasma for the treatment of a surface to be treated of one or more flat substrates 3. To produce an electric field in the process chamber 9, the electrode 5 may be connected, or have been connected, to a radio-frequency supply source (not represented any more specifically), preferably an RF voltage source, while a control unit with associated control means and optionally provided means for plasma diagnostics are present but not represented. The substrate 3 is located directly in front of the grounded counter-electrode 7, it being self-evident that a different way of connecting the electrodes may also be provided. The electrodes 5, 7 are preferably designed for treating substrates with an area of at least 1 m² as a treatment or machining step in the manufacture of high-efficiency thin-film solar modules, for example for amorphous or microcrystalline silicon thin-film solar cells.

The electrodes 5, 7 form two opposing walls of the process chamber 9. The process chamber 9 is located in a vacuum chamber 11, which has a loading and unloading opening 49, which can be closed by a closure device 35. The closure device is optional. The vacuum chamber 11 is formed by a housing 13 of the reactor 1. For sealing from the surroundings, seals 15 are provided.

The vacuum chamber 11 may have any desired spatial form, for example with a round or polygonal, in particular rectangular cross section. The process chamber 9 is formed, for example, as a flat parallelepiped. In another embodiment, the vacuum chamber 11 is itself the process chamber 9.

The electrode 5 is arranged in a holding structure 31 in the vacuum chamber 11 that is formed by the housing rear wall 33. For this purpose, the electrode 5 is accommodated in a recess in the holding structure 31 and is separated from the vacuum chamber wall by a dielectric. A pumping channel 29 is formed by a groove-shaped second recess in the holding structure 31.

The substrate 3 is received by the counter-electrode 7 on its front side, facing the electrode 5, by a mount 34.

Means known per se are provided for introducing and removing gaseous material, it being possible for the gaseous material to be, for example, argon (Ar) and/or hydrogen (H2). In particular, means for transporting a quantity of at least one activatable gas species into a region of the plasma discharge with a quasineutral plasma bulk are provided. A precursor gas which forms layer-creating radicals in a plasma is preferably used as the gas species. The precursor gas is preferably silane (SiH₄), which forms the layer precursor SiH₃ in the plasma by electron collision. In a further embodiment, it is provided that a purifying gas, for example NF₃, is used as the activatable gas species. Introduction and removal of the gaseous material may take place both sequentially and in parallel.

Provided as means for introducing gaseous material is a coating material source 19 with a channel 23, which are connected to a gas distribution device. The gas distribution device is integrated in the electrode 5, but in other embodiments may also be formed separately from the electrode. In the present embodiment, the gas distribution device has a gas outlet plate 25; this comprises a multiplicity of openings which open out into the process chamber 9 and through which the gaseous material can be introduced into the process chamber 9. The gas distribution device is preferably designed in such a way that a homogeneous exposure of the substrate 3 to gas species can be achieved. The multiplicity of outlet openings are preferably distributed uniformly in the gas outlet plate 25, so that the gaseous material is introduced into the process chamber 9 in a uniformly distributed manner.

It is self-evident that the means for introducing gaseous material may also be formed differently from the representation in FIG. 1, and the same applies to the gas distribution device 25.

The reactor 1 comprises a device for setting and/or varying the relative distance between the electrodes, which in the embodiment of FIG. 1 is formed as a sliding pin 41, which can perform a linear movement in the vacuum chamber 11 by means of a bearing plate 43. The sliding pin 41 is connected to the rear side of the counter-electrode 7, facing away from the electrode 5. A drive assigned to the sliding pin 41 is not represented.

In the representation of FIG. 1 it is provided that the counter-electrode 7 covers the recess during the implementation of the plasma treatment. The counter-electrode preferably has contact elements 38 for assigned contact elements 37 of the holding structure, so that the counter-electrode is at the electrical potential of the vacuum chamber 11 during the implementation of the plasma treatment. In a further embodiment, it is provided according to the invention that the counter-electrode 7 has a device for receiving flat substrates which is not represented in FIG. 1 and is formed in such a way that, at least during the implementation of the treatment of the surface to be treated or the treated surface, the substrate or substrates is/are oriented downwardly with an angle alpha in a range between 0° and 90° with respect to the perpendicular direction. In the case of such an arrangement of a substrate, contaminations of the surface to be treated, in particular surface to be coated or coated surface, of the substrate can be avoided or at least reduced, since the particles concerned move downward in the gravitational field, and consequently away from the surface at risk. It is self-evident that, in a further embodiment of the invention, the surface to be treated may be oriented upwardly.

During the loading or unloading of the process chamber 9 with the substrate 3, a relatively great distance between the electrode 5 and the counter-electrode 7 may be provided, and a second, relatively small distance may be provided during implementation of the treatment of the substrate 3.

During the plasma treatment, a plasma (not represented in FIG. 1) is excited by means of a radio-frequency voltage in a region between the electrode 5 and the counter-electrode 7, to be more precise between the gas outlet plate 25 and the substrate 3 mounted on the counter-electrode 5. For the plasma treatment, furthermore, reaction gas is preferably additionally introduced into the plasma in a homogeneously distributed manner via the gas outlet plate 25. The reaction gas is in a quasineutral plasma bulk of the plasma discharge, having a relatively high electron density, between the substrate to be treated and the gas outlet plate 25, as an activated gas species, to which the surface to be treated of the substrate 3 is exposed.

In the present exemplary embodiment, there is a geometrical asymmetry between the electrode 5 and the counter-electrode 7, since the areas of the electrodes are chosen to be of different sizes, causing the formation of a geometrical DC self-bias.

The control unit activates the device in such a way that an asymmetrical plasma discharge is obtained, as explained below.

According to the invention, during the treatment a distance between the substrate 3 (or the surface of the substrate 3) and the gas outlet plate 25 is provided, the value thereof being comparable to s=se+sg, where se denotes a thickness of a plasma boundary layer in front of the electrode and sg denotes a thickness of a plasma boundary layer in front of the counter-electrode. Furthermore, said distance may be chosen such that the quasineutral plasma bulk between the surface region to be treated and the counter-electrode has a linear extent dp, with dp<⅓d, dp<max (se, sg) or dp<0.5s. The linear extent dp of the quasineutral plasma bulk is taken here to be the thickness of the quasineutral plasma bulk parallel to a cross-sectional diameter between the opposing areas of the gas outlet plate 25 and the substrate 3.

In a further exemplary embodiment, analogous to that represented in FIG. 1, the electrode 5 and the counter-electrode 7 are formed geometrically symmetrically and/or the DC self-bias is established by means of a suitable non-harmonic RF excitation voltage, as explained more specifically below.

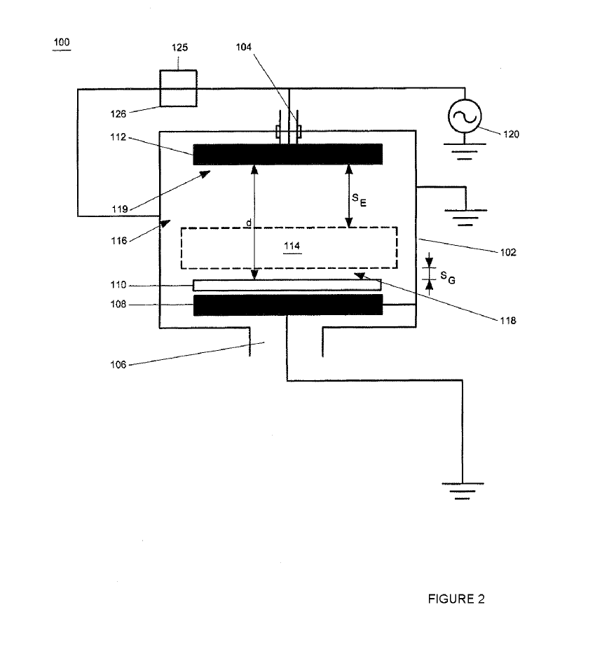

FIG. 2 shows in a simplified representation a plasma device corresponding to FIG. 1, with a vacuum chamber 100, a vacuum chamber wall 102, a gas inlet 104, a gas outlet 106, an electrode 112 connected to an RF voltage supply 120 and a grounded counter-electrode 108. The distance between the electrode 112 and the counter-electrode 110 may optionally be varied. A control unit 125 is provided for the activation of the plasma device. The electrode 112 is preferably provided with an integrated gas distribution device, which however is not represented in FIG. 2. A plasma 114 is produced between the electrodes 108 and 112.

According to the invention, the control unit 125 has means for producing the plasma discharge having the DC self-bias by means of an RF voltage. An RF voltage is produced by means of the RF voltage supply system 120, the RF voltage having two harmonic frequency components with a prescribed relative phase relationship to each other, the higher frequency component being an even-numbered harmonic of the lower frequency component. In the present example, a substrate 110 is arranged directly in front of the grounded electrode 108, but it is self-evident that the substrate could also be arranged in front of the electrode 112—with corresponding adaptation of the gas distribution device. It is also self-evident that the way in which the electrode and the counter-electrode are electrically connected may also differ from the representation shown in FIG. 2; for example, in a further embodiment, one of the frequency components mentioned may be respectively applied to the electrode or the counter-electrode.

As represented in FIG. 2, between the plasma 114 and surfaces which are exposed to the plasma there form plasma boundary layers 116, 118, 119, in the region of which most of the voltage drop occurs, while only a small voltage drop takes place in the region of the quasineutral plasma bulk. According to the invention, the applied RF voltage has the effect of establishing a DC self-bias, which creates an asymmetry in the plasma boundary layers 118 and 119 in front of the electrode 112 and the counter-electrode 108, so that the thickness of the plasma boundary layer S_{E} is different from the thickness of the plasma boundary layer S_{G} in front of the counter-electrode. A more detailed description of this method and corresponding devices for establishing the DC self-bias can be taken from the aforementioned PCT/EP 2008/059133.

According to the invention, the voltage drop across the electrode and the counter-electrode or the substrate surface can be varied by variation of the phase relationship between the two frequency components, which corresponds to an asymmetry of the respective plasma boundary layers even in the case of geometrically symmetrical electrodes.

In a refinement of the invention, the control unit 120 comprises means for introducing a desired ion energy and/or a desired ion flow in the region of the substrate surface. Also provided are control means for setting a power density of the plasma and means for setting an amplitude and/or relative phase relationship of the harmonic frequency components of the RF voltage for setting the ion energy of the plasma and/or the ion flux of the plasma and means for controlling the amplitude and/or relative phase relationship of the harmonic frequency components of the RF voltage.

The control unit 125 is connected to means for plasma diagnostics 126 for determining respectively present values of the thickness of the plasma boundary layer in front of the electrode se and the substrate surface sg. Furthermore, the linear extent dp of the quasineutral plasma bulk may optionally also be measured by the means 126. The measured values can be fed to the control unit as input values.

For the case of an excitation voltage

V_{AC}(t)=315(cos(2πft+0)+cos(4πft))

where f=13.56 MHz and A denotes the phase difference between the two harmonic components of V_{AC}, Monte Carlo simulations of the voltage drop between the electrode and the counter-electrode have been performed in PCT/EP 2008/059133. It was possible thereby to show that, with a grounded counter-electrode for θ=0, the voltage drop as a result of the DC self-bias established with the specified RF voltage at the substrate surface is lower than at the electrode. This corresponds to a lower energy of the ions to which the substrate surface is exposed than to which the electrode is exposed. With a relative phase difference of θ=π/2 between the two harmonic frequency components, the situation is reversed: in this case, the voltage drop across the substrate surface is higher than the voltage drop across the electrode, and accordingly the energy of the ions to which the substrate surface is exposed is higher than the energy of the ions to which the electrode is exposed.

With a symmetrical source function, i.e. f(−x)=f(x), on the other hand, the same values for the two integrals, apart from the signs, are always obtained and the ratio of the fluxes is exactly one.

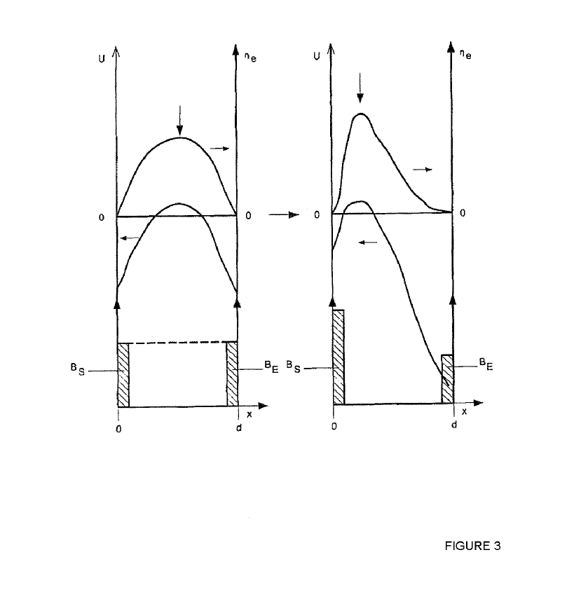

FIG. 3 shows by the example of a plasma coating with silane without DC self-bias (FIG. 3A) and with DC self-bias (FIG. 3B) the electrical potential U (respectively lower curve, left-hand ordinate) and an electron density ne, which represents a concentration of the activated gas species [SiH₃] (respectively upper curve, right-hand ordinate). Values of the x-axis respectively correspond to locations between the electrode and the counter-electrode, where the value x=0 corresponds to the surface of the substrate and x=d corresponds to the surface of the electrode. Also illustrated in FIGS. 3A and 3B, respectively for x=0 and x=d, are a coating rate Bs and Be, or the coating density achieved within a time interval on the substrate surface (on the left) and the surface of the electrode (on the right).

The coating gas silane is preferably introduced homogeneously into the region between the electrode and the substrate by means of a gas distribution device integrated in the electrode. The distance d is chosen to be so small that its value is comparable to s=se+sg.

In FIG. 3a it can be seen for the case of a plasma discharge without DC self-bias that the quasineutral plasma bulk is positioned substantially symmetrically in the region between the electrode and the substrate surface. This position of the quasineutral plasma bulk is equivalent to the region with the highest concentration of activated gas species [SiH₃], corresponding to the downwardly directed arrow of the upper curve, being at the same distance from the electrode and the substrate surface. The electrode and the substrate surface are therefore exposed to substantially the same rate of the activated gas species, with the consequence of an equal coating of the electrode and the substrate surface.

In FIG. 3b it is shown by comparison that the region of the quasineutral plasma bulk has been shifted in the direction of the substrate surface. This is equivalent to a lower potential drop across the substrate surface and a higher potential drop across the electrode. The region of the highest concentration of activated gas species [SiH₃] has likewise been shifted toward the substrate surface and is therefore at a greater distance from the electrode surface. Accordingly, the substrate surface has a higher coating rate Bs than the coating rate Be of the electrode.

1. A method for plasma treatment of a substrate in a plasma device, wherein
the substrate is arranged between an electrode and a counter-electrode with a distance d between a surface region to be treated of the substrate and the electrode,
a capacitively coupled plasma discharge with formation of a DC self-bias is excited between the electrode and the counter-electrode,
in a region of the plasma discharge between the surface region to be treated and the electrode with a quasineutral plasma bulk there is a quantity of at least one activatable gas species to which a surface region to be treated of the substrate is exposed,
wherein a plasma discharge is excited,
in which the distance d has a value in a range between s and 2.5s, with s=se+sg, where se denotes a thickness of a plasma boundary layer in front of the electrode and sg denotes a thickness of a plasma boundary layer in front of the substrate surface to be treated or
in which the quasineutral plasma bulk between the surface region to be treated and the electrode has a linear extent dp, with dp<⅓d, dp<max(se+sg) or dp<0.5s.

2. The method as claimed in claim 1, wherein a relative position of a geometrical center of gravity of the quasineutral plasma bulk between the electrode and the counter-electrode is set or changed in dependence on a value of the distance d and/or of the DC self-bias.

3. The method as claimed in claim 2, wherein the position of said geometrical center of gravity is shifted in a direction of said surface to be treated in relation to the position of said center of gravity in a case of a plasma discharge without DC self-bias.

4. The method as claimed in claim 1, wherein the plasma treatment comprises a plasma coating, a surface modification or an etching of the substrate.

5. The method as claimed in claim 1, wherein an activation of the gas species takes place by radical formation, in the region of the quasineutral plasma bulk.

6. The method as claimed in claim 1, wherein a precursor gas which can form layer-creating radicals in a plasma is used as the activatable gas species.

7. The method as claimed in claim 1, wherein a purifying gas which can form reactive radicals in a plasma is used as the activatable gas species.

8. The method as claimed in claim 1, wherein at least one activatable gas species is transported into the region between the electrode and the counter-electrode by means of an electrode which comprises a gas distribution device with a multiplicity of outlet openings for gas.

9. The method as claimed in claim 1, wherein a geometrical asymmetry of the electrode and the counter-electrode is provided to establish the DC self-bias.

10. The method as claimed in claim 1, wherein an RF voltage which has at least two harmonic frequency components with a prescribed relative phase relationship to each other, at least one of the higher frequency components being an even-numbered harmonic of a lower frequency component, is used for establishing the DC self-bias, when there is geometrical symmetry of the electrode and the counter-electrode.

11. The method as claimed in claim 10, wherein the DC self-bias is changed in dependence on the relative phase relationship between the at least two harmonic frequency components and/or the amplitudes of the at least two harmonic frequency components of the RF voltage.

12. The method as claimed in claim 10, wherein, in dependence on the relative phase relationship between the at least two harmonic frequency components, a setting of a relative ratio of the ion energies at the electrode and the counter-electrode is performed.

13. A device for plasma treatment of a substrate, comprising
means for exciting a capacitively coupled plasma discharge, having a DC self-bias, in a region between an electrode and a counter-electrode and
means for transporting a quantity of at least one activatable gas species into a region of the plasma discharge with a quasineutral plasma bulk, wherein
the substrate is arranged or can be arranged between the electrode and the counter-electrode with a distance d between a surface region to be treated of the substrate and the electrode,
wherein a control unit for activating the device is provided so as to obtain a plasma discharge
in which the distance d has a value in a range between s and 2.5s, with s=se+sg, where se denotes a thickness of a plasma boundary layer in front of the electrode and sg denotes a thickness of a plasma boundary layer in front of the substrate surface to be treated or
in which the quasineutral plasma bulk between the surface region to be treated and the electrode has a linear extent dp, with dp<⅓d, dp<max(se+sg) or dp<0.5s.

14. The device as claimed in claim 13, wherein a device for setting the distance d is provided.

15. The device as claimed in claim 13, wherein the electrode comprises a gas distribution device with a multiplicity of outlet openings for gas with which at least one activatable gas species can be transported into the region between the electrode and the counter-electrode.

16. The device as claimed in claim 13, wherein the control unit comprises means for producing the plasma discharge having the DC self-bias by means of an RF voltage, the RF voltage having at least two harmonic frequency components with a prescribed relative phase relationship to each other and at least one of the higher frequency components being an even-numbered harmonic of a lower frequency component.

17. The device as claimed in claim 13, wherein the control unit comprises
means for introducing a desired ion energy and/or a desired ion flow for exposure of a substrate surface to be treated
control means for setting a power density of the plasma
means for setting an amplitude and/or relative phase relationship of the harmonic frequency components of an RF voltage for setting the ion energy of the plasma and/or the ion flux of the plasma and
means for controlling the amplitude and/or relative phase relationship of the harmonic frequency components of the RF voltage.

18. The device as claimed in claim 13, wherein means for plasma diagnostics are provided for determining respectively present values of a thickness of the plasma boundary layer in front of the electrode se and the substrate surface sg and/or a linear extent dp of the quasineutral plasma bulk, which can be fed to the control unit as input values.
